(19) United States
(12) Patent Application Publication
(10) Pub. No.: US 2015/0103473 A1
(43) Pub. Date: Apr. 16, 2015

(54) ELECTRICAL CONTACTOR WITH CONTROL SIGNAL HEADER CONNECTOR

(71) Applicant: Lennox Industries Inc., Richardson, TX (US)

(72) Inventor: Randall Lee Lisbona, Coppell, TX (US)

(73) Assignee: Lennox Industries Inc., Richardson, TX (US)

(21) Appl. No.: 14/051,032

(22) Filed: Oct. 10, 2013

(51) Int. Cl. H05K 7/00

(52) U.S. Cl. CPC H05K 7/005
USPC 361/679.01

(57) ABSTRACT

A disclosed electrical contactor may include a line-side electrical terminal, a load-side electrical terminal, a switching element coupled between the line-side and load-side electrical terminals, a control signal connector adapted for receiving and routing a control signal, and a control unit coupled between the control signal connector and the switching element and adapted to receive the control signal from the control signal connector and to enable the switching element in response to the control signal. The control signal connector may include a housing and multiple electrical terminals arranged within a cavity, and may include multiple portions each adapted to receive a plug connector. The switching element may be configured to electrically connect the line-side and load-side electrical terminals when enabled. The line-side terminal may be adapted for connection to an electrical conductor carrying an electrical voltage, and the load-side electrical terminal may be adapted for connection to an electrical load.

### BACKGROUND

1. Field of the Invention

The present invention relates to electrical switching devices and, more particularly, to an electrical contactor responsive to a control signal.

2. Description of Related Art

An electrical contactor is an electrically controlled switch used for selectively providing electrical power to one or more load devices. Contactors are used to control electric motors, lighting, heating, capacitor banks, thermal evaporators, and other electrical loads. A typical electrical contactor has control terminals for connecting to a magnetic coil, line terminals for connecting to conductors providing electrical power (i.e., line conductors), and load terminals for connecting to one or more load devices.

Larger heating, ventilating, and air conditioning (HVAC) systems usually include separate “high side” and “low side” units. The high side units are typically located outdoors, and include a compressor, a condenser coil, and a condenser fan. The low side units are typically located indoors, and include an evaporator coil and an evaporator fan. High side units typically include electrical contactors that supply electrical power to the compressor and the condenser fan motor in response to a control signal.

On high side units the control signal may be provided directly to the electrical contactor, or routed through one or more pressure and/or temperature switches. FIGS. 1A-1C illustrate some of ways the control signal may be routed. FIGS. 1A-1C show top plan views of a typical contactor 10 including line-side terminals 12A and 12B, load-side terminals 14A and 14B, a magnetic coil 16, and quick connect control signal terminals 18A and 18B connected to the magnetic coil 16. When an electrical current “I” flows through the magnetic coil 16, the contactor 10 is energized, the load-side terminal 14A is connected to the line-side terminal 12A, and the load-side terminal 14B is connected to the line-side terminal 12B.

FIG. 1A illustrates how a control signal may be routed directly to the control signal terminals of the contactor 10. The quick connect control signal terminal 18A is connected to a common connection “C,” and the quick connect control signal terminal 18B is connected to an electrical voltage “Y” (e.g., from a thermostat). The electrical voltage “Y” formed between the quick connect control signal terminals 18A and 18B is the control signal. When the voltage “Y” is sufficient, the current “I” flows through the magnetic coil 16, and the contactor 10 is energized.

FIG. 1B illustrates how the control signal may be routed to the control signal terminals of the contactor 10 through a high pressure switch 20. The control signal terminal 18A is connected to the common connection “C,” and the control signal terminal 18B is connected to the voltage “Y” via the high pressure switch 20 (shown in the closed position). The contactor 10 is energized only when the voltage “Y” is sufficient and the high pressure switch 20 is in the closed position.

FIG. 1C illustrates how the control signal may be routed to the control signal terminals of the contactor 10 through the high pressure switch 20 and a low pressure switch 22. The control signal terminal 18A is connected to the common connection “C” via the low pressure switch 22 (shown in the closed position), and the control signal terminal 18B is connected to the voltage “Y” via the high pressure switch 20 (shown in the closed position). The contactor 10 is energized only when the voltage “Y” is sufficient and the high pressure switch 20 is in the closed position and the low pressure switch 22 is in the closed position.

A problem arises in that the control signal is routed through different pressure switches on different systems, and the routing of the control signal is typically accomplished via electrical connections made by hand. If a wiring error is made when routing the control signal, such as during original system assembly or subsequent system repair, the wiring error may result in injury to a technician performing the work, damage to the contactor or one or more of the load devices, and/or create an unsafe operating condition.

### SUMMARY

The problems outlined above are at least in part addressed by a novel electrical contactor that may include a line-side electrical terminal, a load-side electrical terminal, a switching element coupled between the line-side electrical terminal and the load-side electrical terminal, a control signal connector adapted for receiving and routing a control signal, and a control unit coupled between the control signal connector and the switching element and adapted to receive the control signal from the control signal connector and to enable the switching element in response to the control signal. The control signal connector may include a housing and multiple electrical terminals arranged within a cavity of the housing, and may include multiple portions each adapted to receive a plug connector. The switching element may be configured to electrically connect the line-side electrical terminal to the load-side electrical terminal when enabled. The line-side terminal may be adapted for connection to an electrical conductor carrying an electrical voltage, and the load-side electrical terminal may be adapted for connection to an electrical load.

### BRIEF DESCRIPTION OF THE DRAWINGS

A better understanding of the various disclosed embodiments can be obtained when the detailed description is considered in conjunction with the following drawings, in which:

FIG. 1A is a top plan view of an electrical contactor illustrating how a control signal may be routed directly to control signal terminals of the contactor;

FIG. 1B is a top plan view of the electrical contactor of FIG. 1 illustrating how the control signal may be routed to the control signal terminals of the contactor through a high pressure switch;

FIG. 1C is a top plan view of the electrical contactor of FIG. 1 illustrating how the control signal may be routed to the control signal terminals of the contactor through the high pressure switch and a low pressure switch;

FIG. 2 is a top plan view of an electrical contactor that may include a header connector adapted for receiving and routing a control signal;

FIG. 3 is a top plan view of the a tab header connector of the electrical contactor of FIG. 2;

FIG. 4 is a wiring diagram of the contactor of FIG. 2;

FIG. 5 is a diagram illustrating how a field connection plug connector can be inserted into the tab header connector to directly control the contactor such that the contactor is enabled when the control signal is present (or active);

FIG. 6 is a diagram illustrating how the field connection plug connector and a plug connector of a high pressure switch can be inserted into the tab header connector to control the contactor such that the contactor is enabled when the control signal is present (or active) and the high pressure switch is closed;

FIG. 7 is a diagram illustrating another embodiment of the tab header connector, and how the field connection plug connector can be inserted into the tab header connector to directly control the contactor such that the contactor is enabled when the control signal is present (or active);

FIG. 8 is a diagram illustrating how the field connection plug connector and the plug connector of the high pressure switch can be inserted into the tab header connector of FIG. 7 to control the contactor such that the contactor is enabled when the control signal is present (or active) and the high pressure switch is closed; and

FIG. 9 is a diagram illustrating how the field connection plug connector, the plug connector of the high pressure switch, and a plug connector of a low pressure switch can be inserted into the tab header connector of FIG. 7 to control the contactor such that the contactor is enabled when the control signal is present (or active), the high pressure switch is closed, and the low pressure switch is closed.

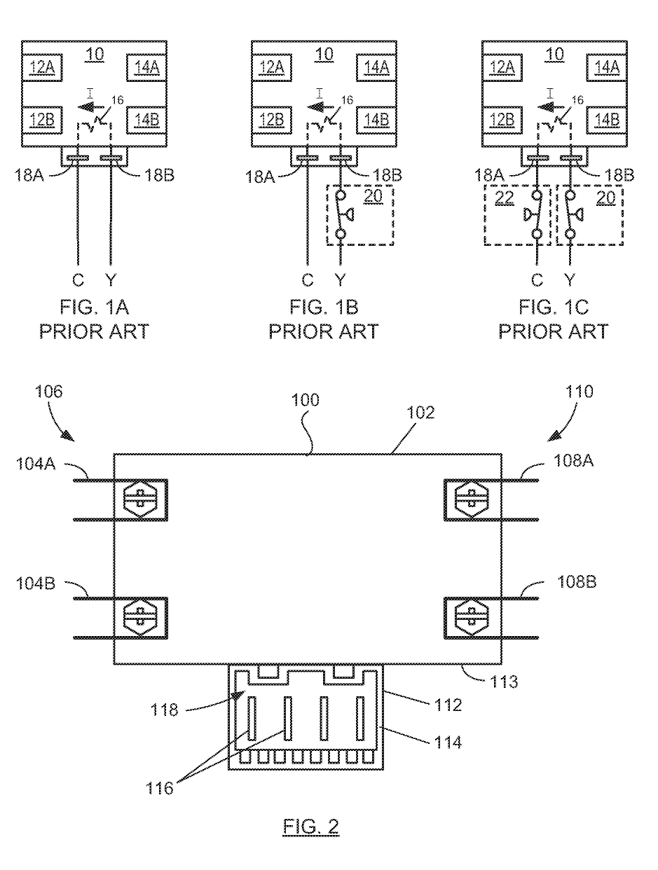

While the invention is susceptible to various modifications and alternative forms, specific embodiments are shown by way of example in the drawings and will be described in detail. It should be understood, however, that the drawings and detailed description are not intended to limit the invention to the particular form disclosed, but on the contrary, the intention is to cover all modifications, equivalents and alternatives falling within the spirit and scope of the invention as defined by the appended claims.

### DETAILED DESCRIPTION

FIG. 2 is a top plan view of an electrical contactor 100 that may include a header connector adapted for receiving and routing a control signal. The header connector aids in routing the control signal, and helps eliminate wiring errors that may injure personnel, damage equipment, or create unsafe operating conditions.

In the embodiment of FIG. 2, the contactor 100 may include a housing 102 having a line side 106 and an opposed load side 110. Spaced apart line-side terminals 104A and 104B are located on the line side 106, and spaced apart load-side terminals 108A and 108B are located on the load side 110. A tab header connector 112, adapted for receiving and routing the control signal, is located on a front surface 113 of the housing 102. The tab header connector 112 is a shrouded header connector with multiple, spaced apart tab terminals arranged in a cavity such that the tab terminals are recessed within the cavity. In the embodiment of FIG. 2, the tab header connector 112 has four spaced apart tab terminals 116 arranged in a cavity 118 such that the tab terminals 116 are recessed within the cavity 118 with respect to an outer face 114 of the tab header connector 112.

In the embodiment of FIG. 2, the control signal used to energize the contactor 100 is an electrical voltage signal. The contactor 100 is enabled when the control signal is present (or active), and is not enabled when the control signal is absent (or inactive).

The line-side terminals 104A and 104B are each adapted for connection to an electrical conductor carrying an electrical voltage (i.e., a line conductor). The line conductors may be, for example, alternating current line conductors carrying voltages that are 180 degrees out of phase. The load-side terminals 108A and 108B are each adapted for connection to an electrical load (e.g., an electrical motor).

In the embodiment of FIG. 2, the line-side terminals 104A and 104B and the load-side terminals 108A and 108B have a screw terminal portion and a quick connect terminal portion. Line conductors may be connected to the line-side terminals 104A and 104B via the screw terminal portions, and line-side devices that are intended to continuously receive electrical power may be powered via the quick connect terminal portions of the line-side terminals 104A and 104B. In other embodiments, the line-side terminals 104A and 104B and the load-side terminals 108A and 108B may be or include other types of terminals, including quick connect terminals, screw terminals, and box lug terminals.

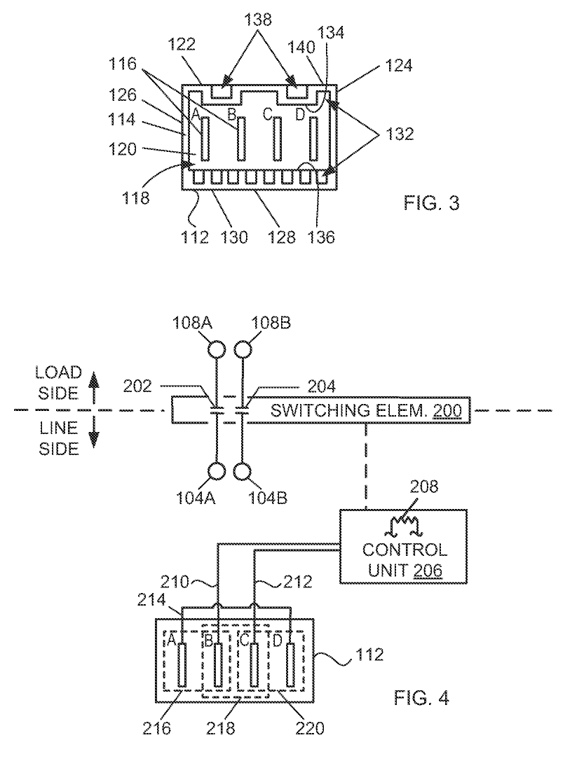

FIG. 3 is a top plan view of the tab header connector 112 of FIG. 2. The tab header connector 112 may include an insulative housing 130 having a base 120 and four walls extending from the base 120; an upper wall 122, a lower wall 128, and two side walls 124 and 126. The base 120, the upper wall 122, the two side walls 124 and 126, and the lower wall 128 form the cavity 118. There are four spaced apart slots in the base 120, and the four tab terminals 116 extend through the slots in the base 120. In FIG. 3, the four tab terminals 116 are labeled “A,” “B,” “C,” and “D” from left to right. The four tab terminals 116 are recessed within the cavity 118 with respect to the outer face 114 of the tab header connector 112. Accordingly, the tab header connector 112 is a shrouded header connector with multiple, spaced apart tab terminals 116 arranged in the cavity 118 such that the tab terminals 116 are recessed within the cavity 118 with respect to the outer face 114 of the tab header connector 112.

As shown in FIG. 3, multiple keying and/or polarization slots 132 are formed in an inner surface 134 of the upper wall 122, and in an inner surface 136 of the lower wall 128. In some embodiments, the tab header connector 112 has multiple portions (see FIG. 4 and the description below). Each portion of the tab header connector 112 has one or more keying and/or polarization slots 132, and the keying and/or polarization slots 132 are configured differently such that only corresponding plug connector(s) will fit in the portions of the tab header connector 112.

In the embodiment of FIG. 3, two latch windows 138 are formed in an outer surface 140 of the upper wall 122. Each of the latch windows 138 is configured to receive a male latch member of a plug connector. When a plug connector is inserted into a portion of the tab header connector 112, a male latch member of the plug connector may engage the housing 130 via one or both of the latch windows 138.

In the embodiment of FIGS. 2-3, the tab terminals 116 include flat, rectangular mating “tab” portions made of an electrically conductive material (e.g., a metal), and are male terminals adapted to engage corresponding female terminals (e.g., of a plug connector). Other configurations of the tab terminals 116 are also possible. For example, in other embodiments the tab terminals 116 may be pin terminals, cylindrical “bullet” connectors adapted to engage corresponding female terminals, or female terminals adapted to engage corresponding male terminals (e.g., of a plug connector).

In the embodiment of FIGS. 2-3, the tab header connector 112 conforms to the Raster Anschluss Steck Tecknik (RAST) standard for tab header connectors. In other embodiments the tab header connector 112 may or may not conform to a header connector standard.

FIG. 4 is a wiring diagram of the contactor 100 of FIG. 2. FIG. 4 also shows the different portions of the tab header connector 112. In the embodiment of FIG. 4, the tab header connector 112 includes three different portions 216, 218, and 220, each of which is adapted to receive a plug connector. Each of the portions 216, 218, and 220 includes two adjacent tab terminals 116 and a surrounding portion of the housing 130 of the tab header connector 112 (see FIG. 3). More specifically, the portion 216 includes the tab terminals “A” and “B” and a surrounding portion of the housing 130, the portion 218 includes the tab terminals “B” and “C” and a surrounding portion of the housing 130, and the portion 220 includes the tab terminals “C” and “D” and a surrounding portion of the housing 130. Each of the portions 216, 218, and 220 has one or more keying and/or polarization slots 132 (see FIG. 3), and the keying and/or polarization slots 132 are configured differently such that only corresponding plug connector(s) will fit in the portions 216, 218, and 220. In the embodiment of FIG. 4, the three different portions 216, 218, and 220 overlap one another. In other embodiments, the portions of the tab header connector may or may not overlap one another.

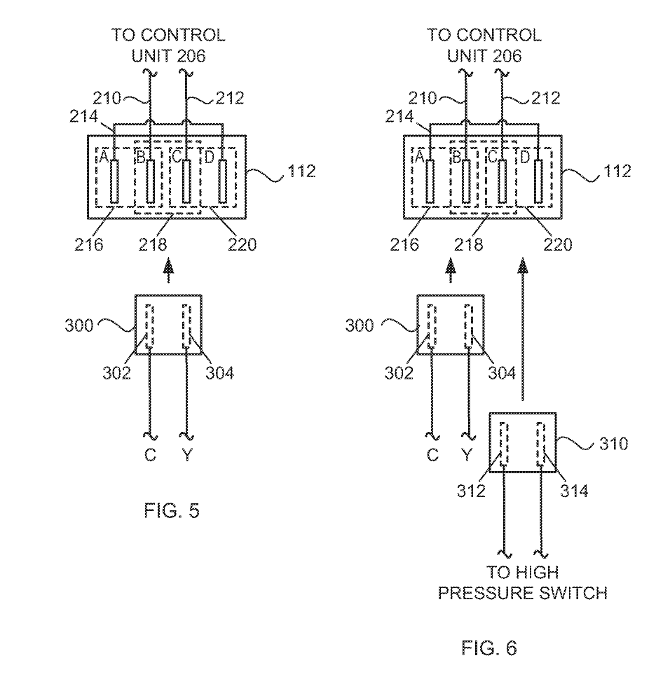

As indicated in FIG. 4, the contactor 100 may include a switching element 200 and a control unit 206. The control unit 206 is coupled to the tab header connector 112 and to the switching element 200. The tab header connector 112 receives and routes the control signal. The control unit receives the control signal from the tab header connector 112, and enables the switching element 200 in response to the control signal. More specifically, the control unit 206 is connected to the tab terminal “B” of the tab header connector 112 via an electrical conductor (e.g., wire) 210, and to the tab terminal “C” of the tab header connector 112 via an electrical conductor (e.g., wire) 212. An electrical conductor 214 (e.g., a short wire or jumper) connects the tab terminal “A” of the tab header connector 112 to the tab terminal “D.” The electrical conductor 214 allows the tab header connector 112 to route the control signal directly to the control unit 206, or through an external switch (e.g., a pressure switch) before routing the control signal to the control unit 206 (see FIGS. 5 and 6 and the descriptions below).

In the embodiment of FIG. 4, the control unit 206 may include a magnetic coil 208, and the switching element 200 may include two sets of contacts 202 and 204 operated in unison. When the control unit 206 receives the control signal and the control signal is active, the control unit 206 may apply electrical voltage to the magnetic coil 208, causing electrical current to flow through the magnetic coil 208, and creating a magnetic field around the magnetic coil 208. This magnetic field is coupled to the switching element 200, and causes the contacts 202 and 204 to close. When the magnetic field is not present, the contacts 202 and 204 are open. In other embodiments, the switching element 200 and/or the control unit 206 may include semiconductor devices, and the switching mechanism including the switching element 200 and/or the control unit 206 may be termed a solid state mechanism. In such solid state embodiments, the Control Unit 206 may not include the magnetic coil 208.

When the contacts 202 are open, the load-side terminal 108A is electrically isolated from the line-side terminal 104A. When the contacts 202 are closed, the load-side terminal 108A is electrically connected to the line-side terminal 104A. When the contacts 204 are open, the load-side terminal 108B is electrically isolated from the line-side terminal 104B. When the contacts 204 are closed, the load-side terminal 108B is electrically connected to the line-side terminal 104B.

In some embodiments, the switching element 200 may include a single set of contacts, either the contacts 202 or the contacts 204. For example, in some embodiments, the switching element 200 may include only the set of contacts 202, and an electrical conductor may be connected between the line-side terminal 104B and the load-side terminal 108B.

FIG. 5 is a diagram illustrating how a field connection plug connector 300 can be inserted into the tab header connector 112 to directly control the contactor 100 such that the contactor 100 is enabled when the control signal is present (or active). The field connection plug connector 300 includes two female terminals 302 and 304 arranged to make physical and electrical contact with two adjacent tab terminals 116 (see FIGS. 2 and 3) of the tab header connector 112. In the embodiment of FIG. 5, the portion 218 of the tab header connector 112 is adapted to receive the field connection plug connector 300. More specifically, the field connection plug connector 300 has one or more ridges on an outer surface that mate with the one or more keying and/or polarization slots 132 (see FIGS. 2 and 3) of the portion 218 of the tab header connector 112 such that the field connection plug connector 300 will physically fit in the portion 218. When the field connection plug connector 300 is inserted into the portion 218, the female terminals 302 and 304 of the field connection plug connector 300 make physical and electrical contact with two adjacent tab terminals “B” and “C” of the portion 218 of the tab header connector 112.

In the embodiment of FIG. 5, the female terminal 302 of the field connection plug connector 300 is connected to a common connection “C,” and the female terminal 304 of the field connection plug connector 300 is connected to an electrical voltage “Y” (e.g., from a thermostat). The electrical voltage “Y” formed between the female terminals 302 and 304 of the field connection plug connector 300 is the control signal. When the field connection plug connector 300 is inserted into the portion 218 of the tab header connector 112, the tab header connector 112 routes the control signal directly to the control unit 206. The contactor 100 is enabled when the control signal is present (or active), and is not enabled when the control signal is absent (or inactive).

FIG. 6 is a diagram illustrating how the field connection plug connector 300 and a plug connector 310 of a high pressure switch can be inserted into the tab header connector 112 to control the contactor 100 such that the contactor 100 is enabled when the control signal is present (or active) and the high pressure switch is closed. The plug connector 310 includes two female terminals 312 and 314 arranged to make physical and electrical contact with two adjacent tab terminals 116 (see FIGS. 2 and 3) of the tab header connector 112. The female terminals 312 and 314 are connected to two terminals of the high pressure switch such that the female terminals 312 and 314 are electrically isolated from one another when the high pressure switch is open, and electrically connected to one another when the high pressure switch is closed.

In the embodiment of FIG. 6, the portion 216 of the tab header connector 112 is also adapted to receive the field connection plug connector 300. More specifically, the one or more ridges on the outer surface of the field connection plug connector 300 mate with the one or more keying and/or polarization slots 132 (see FIGS. 2 and 3) of the portion 216 of the tab header connector 112 such that the field connection plug connector 300 will physically fit in the portion 216 of the tab header connector 112. When the field connection plug connector 300 is inserted into the portion 216, the female terminals 302 and 304 of the field connection plug connector 300 make physical and electrical contact with two adjacent tab terminals “A” and “B” of the portion 216 of the tab header connector 112.

In the embodiment of FIG. 6, the portion 220 of the tab header connector 112 is adapted to receive the plug connector 310 of the high pressure switch. More specifically, the plug connector 310 has one or more ridges on an outer surface that mate with the one or more keying and/or polarization slots 132 (see FIGS. 2 and 3) of the portion 220 of the tab header connector 112 such that the plug connector 310 will physically fit in the portion 220. When the plug connector 310 is inserted into the portion 220, the female terminals 312 and 314 of the plug connector 310 make physical and electrical contact with two adjacent tab terminals “C” and “D” of the portion 220 of the tab header connector 112.

In the embodiment of FIG. 6, when the field connection plug connector 300 is inserted into the portion 216 of the tab header connector 112, and the plug connector 310 of the high pressure switch is inserted into the portion 220 of the tab header connector 112, the control signal is routed to the control unit 206 (see FIG. 4) via the electrical conductor 214 that connects the tab terminal “A” of the tab header connector 112 to the tab terminal “D” such that the control signal must pass through the high pressure switch. The tab header connector 112 thus connects the high pressure switch in series with the control unit 206. The tab header connector 112 routes the control signal through the high pressure switch before routing the control signal to the control unit 206. The contactor 100 is enabled when the control signal is present (or active) and the high pressure switch is closed, and is not enabled when the control signal is absent (or inactive) or the high pressure switch is open.

It is noted that in the embodiment of FIGS. 5 and 6, the portions 216 and 218 of the tab header connector 112 are adapted to receive the field connection plug connector 300, and the portion 220 of the tab header connector 112 is adapted to receive the plug connector 310 of the high pressure switch. In other embodiments, the high pressure switch may be another type of electrical switch, such as, for example, a low pressure switch, a high/low temperature switch, or a manual switch.

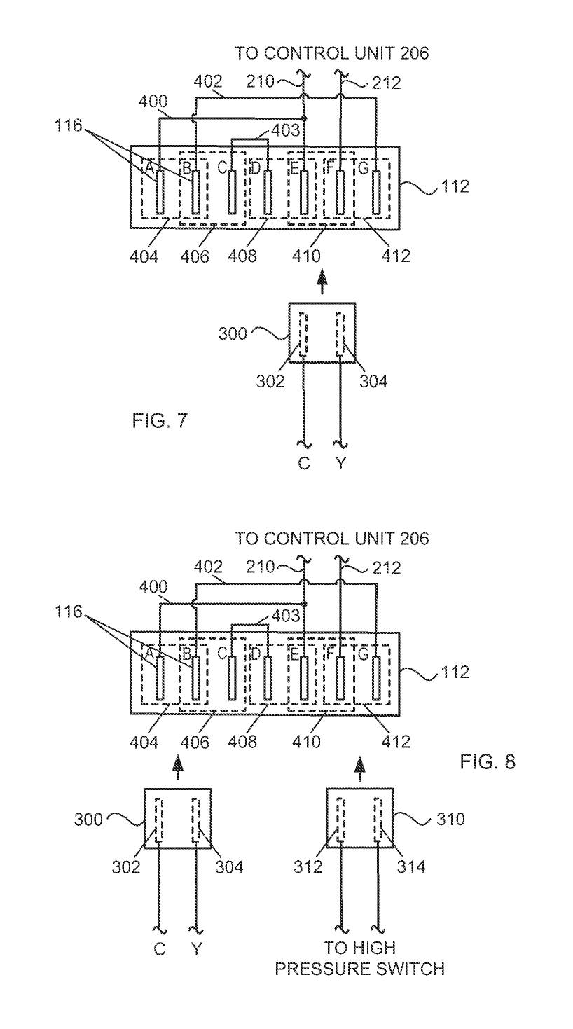

FIG. 7 is a diagram illustrating another embodiment of the tab header connector 112, and how the field connection plug connector 300 can be inserted into the tab header connector 112 to directly control the contactor 100 such that the contactor 100 is enabled when the control signal is present (or active). In the embodiment of FIG. 7, the tab header connector 112 includes seven tab terminals 116 (see FIGS. 2 and 3) labeled “A,” “B,” “C,” “D,” “E,” “F,” and “G” from left to right. The tab header connector 112 includes five different portions 404, 406, 408, 410, and 412, each of which is adapted to receive a plug connector. Each of the portions 404, 406, 408, 410, and 412 includes two adjacent tab terminals 116 and a surrounding portion of the housing 130 of the tab header connector 112 (see FIG. 3). More specifically, the portion 404 includes the tab terminals “A” and “B” and a surrounding portion of the housing 130, the portion 406 includes the tab terminals “B” and “C” and a surrounding portion of the housing 130, and the portion 408 includes the tab terminals “D” and “E” and a surrounding portion of the housing 130. The portion 410 includes the tab terminals “E” and “F” and a surrounding portion of the housing 130, and the portion 412 includes the tab terminals “F” and “G” and a surrounding portion of the housing 130. Each of the portions 404, 406, 408, 410, and 412 has one or more keying and/or polarization slots 132 (see FIG. 3), and the keying and/or polarization slots 132 are configured differently such that only corresponding plug connector(s) will fit in the portions 404, 406, 408, 410, and 412. In the embodiment of FIG. 7, some of the portions 404, 406, 408, 410, and 412 overlap one another, and others do not.

In the embodiment of FIG. 7, the control unit 206 (see FIG. 4) is connected to the tab terminal “E” of the tab header connector 112 via the electrical conductor 210, and to the tab terminal “F” of the tab header connector 112 via the electrical conductor 212. An electrical conductor 400 (e.g., a short wire or jumper) connects the tab terminal “A” of the tab header connector 112 to the tab terminal “E,” a second electrical conductor 402 (e.g., a short wire or jumper) connects the tab terminal “B” to the tab terminal “G,” and a third electrical conductor 403 (e.g., a short wire or jumper) connects the tab terminal “C” to the tab terminal “D.” The electrical conductors 400, 402, and 403 allow the tab header connector 112 to route the control signal directly to the control unit 206, or through one or more external switches (e.g., pressure switches).

In the embodiment of FIG. 7, the portion 410 of the tab header connector 112, including the adjacent tab terminals “E” and “F,” is adapted to receive the field connection plug connector 300 as described above. When the field connection plug connector 300 is inserted into the portion 410, the female terminals 302 and 304 of the field connection plug connector 300 make physical and electrical contact with two adjacent tab terminals “E” and “F” of the portion 410 of the tab header connector 112. When the field connection plug connector 300 is inserted into the portion 410 of the tab header connector 112, the contactor 100 is enabled when the control signal is present (or active), and is not enabled when the control signal is absent (or inactive).

FIG. 8 is a diagram illustrating how the field connection plug connector 300 and the plug connector 310 of the high pressure switch can be inserted into the tab header connector 112 of FIG. 7 to control the contactor 100 such that the contactor 100 is enabled when the control signal is present (or active) and the high pressure switch is closed. In the embodiment of FIG. 8, the portion 404 of the tab header connector 112 is also adapted to receive the field connection plug connector 300, and the portion 412 of the tab header connector 112 is adapted to receive the plug connector 310 of the high pressure switch as described above.

When the field connection plug connector 300 is inserted into the portion 404, the female terminals 302 and 304 of the field connection plug connector 300 make physical and electrical contact with two adjacent tab terminals “A” and “B” of the portion 404 of the tab header connector 112. When the plug connector 310 is inserted into the portion 412, the female terminals 312 and 314 of the plug connector 310 make physical and electrical contact with the two adjacent tab terminals “F” and “G” of the portion 412 of the tab header connector 112.

In the embodiment of FIG. 8, when the field connection plug connector 300 is inserted into the portion 404 of the tab header connector 112, and the plug connector 310 of the high pressure switch is inserted into the portion 412 of the tab header connector 112, the control signal is routed to the control unit 206 (see FIG. 4) via the electrical conductors 400 and 402 such that the control signal must pass through the high pressure switch. The contactor 100 is enabled when the control signal is present (or active) and the high pressure switch is closed, and is not enabled when the control signal is absent (or inactive) or the high pressure switch is open.

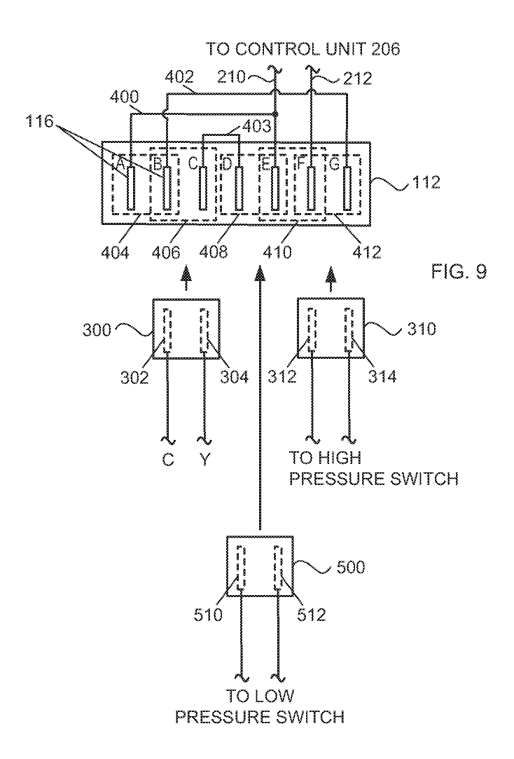

FIG. 9 is a diagram illustrating how the field connection plug connector 300, the plug connector 310 of the high pressure switch, and a plug connector 500 of a low pressure switch can be inserted into the tab header connector 112 of FIG. 7 to control the contactor 100 such that the contactor 100 is enabled when the control signal is present (or active), the high pressure switch is closed, and the low pressure switch is closed. The plug connector 500 of the low pressure switch includes two female terminals 510 and 512 arranged to make physical and electrical contact with two adjacent tab terminals 116 (see FIGS. 2 and 3) of the tab header connector 112. The female terminals 510 and 512 are connected to two terminals of the low pressure switch such that the female terminals 510 and 512 are electrically isolated from one another when the low pressure switch is open, and electrically connected to one another when the low pressure switch is closed.

In the embodiment of FIG. 9, the portion 406 of the tab header connector 112 is also adapted to receive the field connection plug connector 300, the portion 408 of the tab header connector 112 is adapted to receive the plug connector 500 of the low pressure switch, and the portion 412 is adapted to receive the plug connector 310 of the high pressure switch. When the field connection plug connector 300 is inserted into the portion 406, the female terminals 302 and 304 of the field connection plug connector 300 make physical and electrical contact with two adjacent tab terminals “B” and “C” of the portion 406 of the tab header connector 112. When the plug connector 500 is inserted into the portion 408, the female terminals 510 and 512 of the plug connector 500 make physical and electrical contact with the two adjacent tab terminals “D” and “E” of the portion 408 of the tab header connector 112. When the plug connector 310 is inserted into the portion 412, the female terminals 312 and 314 of the plug connector 310 make physical and electrical contact with the two adjacent tab terminals “F” and “G” of the portion 412 of the tab header connector 112.

In the embodiment of FIG. 9, when the field connection plug connector 300 is inserted into the portion 406 of the tab header connector 112, the plug connector 500 of the low pressure switch is inserted into the portion 408 of the tab header connector 112, and the plug connector 310 of the high pressure switch is inserted into the portion 412 of the tab header connector 112, the control signal is routed to the control unit 206 (see FIG. 4) via the electrical conductors 402 and 403 such that the control signal must pass through the high pressure switch and the low pressure switch. The contactor 100 is enabled when the control signal is present (or active) and the high pressure switch is closed and the low pressure switch is closed, and is not enabled when the control signal is absent (or inactive) or the high pressure switch is open or the low pressure switch is open.

It is noted that in the embodiment of FIGS. 7-9, the portions 404, 406, and 410 of the tab header connector 112 are adapted to receive only the field connection plug connector 300, the portion 408 is adapted to receive only the plug connector 500 of the low pressure switch, and the portion 412 is adapted to receive only the plug connector 310 of the high pressure switch. In other embodiments, the low pressure switch may be another type of electrical switch (e.g., a high pressure switch, a high/low temperature switch, or a manual switch), and the high pressure switch may be another type of electrical switch (e.g., a low pressure switch, a high/low temperature switch, or a manual switch).

Numerous variations and modifications will become apparent to those skilled in the art once the above disclosure is fully appreciated. It is intended that the following claims be interpreted to embrace all such variations and modifications.

What is claimed is:

1. An electrical contactor, comprising:
a line-side electrical terminal adapted for connection to an electrical conductor carrying an electrical voltage;
a load-side electrical terminal adapted for connection to an electrical load;
a switching element coupled between the line-side electrical terminal and the load-side electrical terminal, and configured to electrically connect the line-side electrical terminal to the load-side electrical terminal when enabled;
a control signal connector adapted for receiving and routing a control signal, wherein the control signal connector comprises a housing and a plurality of electrical terminals arranged within a cavity of the housing, and wherein the control signal connector comprises multiple portions each adapted to receive a plug connector; and
a control unit coupled between the control signal connector and the switching element, and adapted to receive the control signal from the control signal connector and to enable the switching element in response to the control signal.

2. The electrical contactor as recited in claim 1, wherein the terminals of the control signal connector are arranged in the cavity such that the terminals are recessed within the cavity with respect to an outer face of the control signal connector.

3. The electrical contactor as recited in claim 1, wherein the electrical terminals of the control signal connector are tab terminals.

4. The electrical contactor as recited in claim 1, wherein each of the portions of the control signal connector comprises two adjacent electrical terminals and a surrounding portion of the housing.

5. The electrical contactor as recited in claim 1, wherein each of the portions of the control signal connector are mechanically coded to receive a plug connector.

6. The electrical contactor as recited in claim 1, wherein the control signal connector conforms to the Raster Anschluss Steck Tecknik (RAST) standard.

7. The electrical contactor as recited in claim 1, further comprising an electrical conductor connected between electrical terminals of two different portions of the control signal connector such that the electrical conductor allows the control signal to be routed through the two different portions of the control signal connector.

8. The electrical contactor as recited in claim 1, wherein at least two of the portions of the control signal connector are adapted to receive a plug connector conveying the control signal.

9. The electrical contactor as recited in claim 1, wherein at least one of the portions of the control signal connector is adapted to receive a plug connector of an electrical switch.

10. The electrical contactor as recited in claim 9, wherein the electrical switch is a pressure switch, a temperature switch, or a manual switch.

11. The electrical contactor as recited in claim 1, wherein the line-side electrical terminal and the load-side electrical terminal comprise a quick connect terminal, a screw terminal, or a box lug terminal.

12. The electrical contactor as recited in claim 1, wherein the switching element comprises a pair of electrical contacts, and wherein the control unit comprises a magnetic coil.

13. The electrical contactor as recited in claim 1, wherein the switching element and the control unit comprise semiconductor devices.

14. An electrical contactor, comprising:
a line-side electrical terminal adapted for connection to an electrical conductor carrying an electrical voltage;
a load-side electrical terminal adapted for connection to an electrical load;
a switching element coupled between the line-side electrical terminal and the load-side electrical terminal, and configured to electrically connect the line-side electrical terminal to the load-side electrical terminal when enabled;
a control signal connector adapted for receiving and routing a control signal, wherein the control signal connector comprises a housing and a plurality of electrical terminals arranged within a cavity of the housing, and wherein the control signal connector comprises at least two portions adapted to receive a plug connector conveying the control signal and at least one portion adapted to receive a plug connector of a pressure switch; and
a control unit coupled between the control signal connector and the switching element, and adapted to receive the control signal from the control signal connector and to enable the switching element in response to the control signal.

15. The electrical contactor as recited in claim 14, wherein the terminals of the control signal connector are arranged in the cavity such that the terminals are recessed within the cavity with respect to an outer face of the control signal connector.

16. The electrical contactor as recited in claim 14, wherein the electrical terminals of the control signal connector are tab terminals.

17. The electrical contactor as recited in claim 14, wherein each of the portions of the control signal connector comprises two adjacent electrical terminals and a surrounding portion of the housing.

18. The electrical contactor as recited in claim 14, wherein each of the portions of the control signal connector are mechanically coded to receive a plug connector.

19. The electrical contactor as recited in claim 14, wherein the control signal connector conforms to the Raster Anschluss Steck Tecknik (RAST) standard.

20. The electrical contactor as recited in claim 14, further comprising an electrical conductor connected between electrical terminals of two different portions of the control signal connector such that the electrical conductor allows the control signal to be routed through the two different portions of the control signal connector.
